(19) United States
(12) Patent Application Publication
(10) Pub. No.: US 2005/0018731 A1
(43) Pub. Date: Jan. 27, 2005

(54) Laser equivalent surface apparatus and method for measuring active detective system performance

(75) Inventors: Jean-Luc Paradis, Champigny-sur-Marne (FR); Joel Chablat, Villebon sur Yvette (FR); Jacques Vesque, Fontenay-aux-roses (FR); Jose Garcia, Champlan (FR)

Correspondence Address: PARKHURST & WENDEL, L.L.P., 1421 PRINCE STREET, SUITE 210, ALEXANDRIA, VA, 22314-2805, US

(73) Assignee: ETAT FRANCAIS represente par le Delegue General, Arcueil Cedex (FR)

(21) Appl. No.: 10/736,977

(22) Filed: Dec. 17, 2003

(30) Foreign Application Priority Data
Dec. 20, 2002 (FR) 02 16275

(51) Int. Cl. H01S 5/00

(52) U.S. Cl. 372/50

(57) ABSTRACT

A particular object of the present invention is apparatus having a perfectly known laser equivalent surface and able to measure the performance of an active detection unit, characterized in that said apparatus comprises a radial attenuator to limit the apparatus' aperture and exhibiting a radial transmission function represented by a bell-shape curve.

The present invention relates to measuring the performance of sight laser detection systems (SLD) and more particularly its objective is to improve devices with perfectly known, and optionally adjustable laser cross section (LCS).

Many observing instruments are fitted in their image plane, also called the image focus, with a reflecting or a diffuse surface. Said surface, for example, is a sight's or a binoculars′ reticle slide, a detecting surface in a still or movie camera whether using film or being digital. Such a surface also is constituted by the eye's retina. This surface absorbs or transmits part of the incident power constituting the useful signal, for instance that of a photographic picture, a video signal or of a retinal image, and reflects in specular or diffuse manner another portion of reflected portion. This incident power is picked up in part by the image forming optics which, according to the light inverse return principle, returns the light in highly directional manner into the plane of the source where it is focused.

If another observing instrument is situated in the immediate vicinity of the luminous object, also called the source, or is virtually superposed on it by optical means, said other instrument will receive the focused flux from the first observing system.

If the object is an intense light source, for instance a laser, the focused return beam will be able to create a first system image which is much more luminous than its ambience on the said second observing system.

This is the phenomenon which causes the red-eye effect in photos taken by flash when latter is too close to the camera's lens. Instead of appearing to be black, the eye pupil is lit up in red due to the substantial diffusion of this color by the human eye retina.

The same phenomenon makes cat' eyes luminous in the night when they are illuminated by automobile headlights. This reflection is sometimes called the “cat eye effect”.

If the observed object—in this case the second observing system—illuminates by means of a laser that observes it, here the first system which is called the “sighting optics”, then this first system returns a substantial luminous power in the precise direction of the transmitting laser. Said power is evaluated while determining, under well defined test conditions, which surface should have an imagined object that, subjected to the same illumination, at zero absorption and while uniformly diffusing the light into all of space, would return the same light intensity as the sighting optics in the exact direction of the laser. In that case the sighting optics has an LCS equal to the surface. Accordingly an optics of several cm² may exhibit an LCS of several hundred m². This merely means that as much power as from the imagined object having such a surface is sent back to the observer.

The definition of “laser equivalent surface” is broader but herein only the monostatic LCS will be considered. In this instance the laser transmitter and the detector receiving the reflected light are near enough to one another to be considered coincident when viewed from the first observing system.

The present invention relates to all of optics and the expression “light” herein may cover any field within the spectrum of electromagnetic radiation.

The present invention mainly relates to very remote observing instruments, and, without however thereby restricting the invention's applicability, the image plane and the focal plane of the first observing system shall be considered coincident.

The magnitude of the LCS is a significant parameter of observing systems because it determines their concealment with regard to an active observing system employing this property. An active detecting system means it contains a light source.

To validate these instruments with respect to this threat of being detected, it is necessary to measure the magnitude of their LCS. This may be done using empirical calibration by means of one or several instruments of known LCS (calibrating the LCS testing equipment).

To measure detection system performance using that property, instruments must be used displaying several LCS values or one instrument of which the LCS can be adjusted in a given manner.

In a standard observing instrument, the LCS depends on many parameters among which include geometric aberrations or the reflection coefficient of the image plane at the considered wavelength (which may be affected by interferences), said parameters being considered by the system designer with respect to image quality optics, but not with respect to concealment. Therefore different instruments offering image quality meeting the same standards may exhibit very different LCSs. Moreover, a single instrument may have a LCS magnitude that varies in unexpected manner as a function of wavelength or field angle.

Accordingly such instruments cannot be used as references for LCSs meeting the above cited needs. Nor is it practical to use a single diffusing surface, which would be far too large. Plain spherical mirrors might be used, however each wavelength would require a mirror having a different radius of curvature or a different reflection coefficient for each LCS magnitude.

However it is known to use reference devices to measure LCSs.

Thus, the WO02/33438 patent application describes a device with a known LCS which may be continuously adjusted, the device including a lens, a mirror configured to constitute at least one optic axis of said device, and means adjusting the distance between lens and mirror. In one embodiment variation, said device includes an attenuating filter able to vary or adjust the device's LCS.

Other device wherein the back-reflected light intensity, that is, of light reflected in the axis of illumination, is mainly linked as in the above cited patent to the geometric properties of the optics system, or, on the contrary, to its diffraction, also are known and employed. As regards the former category, it includes reflecting portions of a sphere, and the latter diffraction-limited systems such as reflecting trirectangular trihedra constituting the so-called cube corners, or systems constituted by a lens and a reflecting or diffusing surface placed at its focus.

In one device of the WO02/33438 patent application, the mirror must be placed at a distance x away from the len' focus, where x must be large enough to assure that the focusing error circle shall be large with regard to the image spot.

This precaution is necessary to preclude the problems entailed by the theoretically focused, or slightly defocused instruments which, depending on the highly critical position adjustment along the X axis, and in the field of the instrument may exhibit LCSs varying from zero to a very high value in apparently random manner.

This LCS variation arising as a function of instrument adjustment for an instrument theoretically at infinity—by LCS definition—also arises as a function of the distance at which said instrument is used. Thus, even a perfect cube corner without any adjustment means shall exhibit an LCS of which the value goes to zero at some distances.

These modulations of the LCS values are difficult to control and they spread more or less depending on the coherence of the incident light, the geometric system aberrations, the system's manufacturing defects and the distance at which such a system is used, as a result of which the scope of application of such systems is limited.

The object of the present invention is to circumvent said limitations, thereby increasing the scope of application and the reliability of such systems in the applicable fields, even to continuously pass from a geometrically based system to one which is diffraction-limited.

In a first embodiment mode of the present invention, its design solution is a device with perfectly known LCS, which is characterized in that it comprises a radial attenuator able to modify the device aperture and exhibiting a radial transmission function in the shape of a bell curve.

In one particular feature, said radial attenuator exhibits at least one of the following features:
it is configured in the pupil plane,
its transmission function includes symmetry of revolution
its transmission function decreases monotonely from the pupil's center to its rim,
the surface slope representing the transmission function is continuous everywhere on the pupil
its transmission function is sinusoidal, for instance in sin², cos², cos⁴ . . .

In one particular feature, said attenuator comprises a lens and a mirror placed so as to form at least one device optic axis OZ and at a distance x from the focal image F′, x being other than 0.

The device optic axis is defined as being the axis passing through the len' optic center and perpendicular to the mirror. In the case of spherical mirror, the center of which is the len' optic center, there will be an infinity of device optic axes passing through the len' optic center and perpendicular to said mirror. In many cases the device optic axis coincides with the lens optic axis, which passes through the len' center of curvature and through the image focus. This shall be the case in particular when a plane mirror is placed perpendicularly to the len' optic axis.

In another embodiment of said device, it comprises means adjusting the distance between lens and mirror.

The relative motion implemented by said adjusting means between the lens and the mirror preferably shall take place while the mutually perpendicular configuration of said device optic axis and the mirror is preserved.

In a particular embodiment, the lens is stationary and comprises means adjusting the mirror position to allow adjusting the distance between lens and mirror.

In another embodiment, the mirror is stationary and is fitted with means that adjust lens position and the distance between lens and mirror.

The adjusting means are conventional and for instance may comprise helical motion implemented for instance manually or being motor driven illustratively using an electrical stepping motor.

Control means of which the setpoint may be stated in LCS may be associated with the adjusting means.

In another preferred feature, said mirror is plane and preferably shall be placed perpendicularly to said device optic axis in order that most of the incident light be returned in the direction of the lens.

In yet another feature of the present invention, its device consists either of a reflecting portion of a sphere which may or may not comprise a radially reflecting treatment of which the reflection coefficient is a bell curve, or of a reflecting trirectangular dihedron, or of a lens with a diffusing surface placed at its focus or near it, or of a lens with a reflecting surface placed at its focus or near it.

“Near it” denotes a distance less than the focusing distance defined by the distance at which the focusing error circle exhibits a diameter equal to that of the image spot.

In another feature, a device of the present invention comprises alignment means to align it with a second device, such as an external detection system, an active SLD system, in order to render said second device collinear with the optic axis, such alignment means optionally comprising pointing elements illustratively a pointing telescope or a front sight and a hole. Also, the pointing means may be configured laterally off the optic axis and masking elements for the pointing means may be used in order not to alter the LCS of the device of the invention.

Moreover an attenuating filter may be mounted on the lens and preferably none of its sides shall be perpendicular to said optic axis.

The present invention also relates to a method to adjust the LCS of device of the invention to a predetermined value, said method being characterized in that it displaces said mirror along the len' optic axis until attaining a distance x from the focal plane, the x value being determined by the equation below
x=(_{c}RTo²f⁴/LCS)^{1/2}
where R is the mirror's reflection factor, To is the len' transmission factor and f is the len' focal length.

Other advantages and features of the present invention are elucidated in the following description of different embodiment modes of the invention and in relation to the appended Figures.

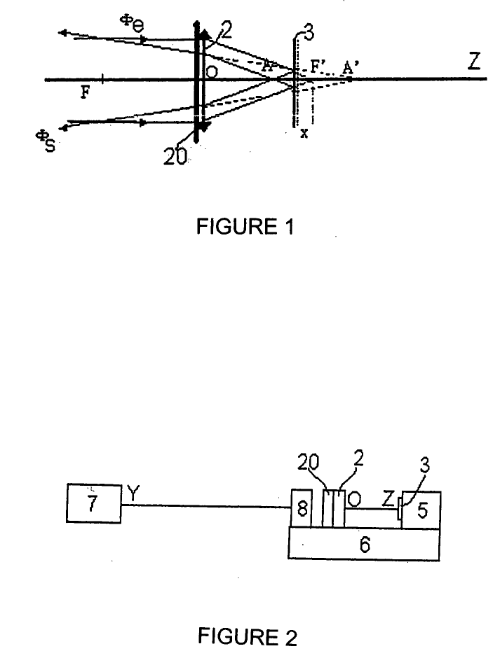

FIG. 1 diagrammatically shows the means of an embodiment variation of the invention.

FIG. 2 shows a second embodiment variation of the invention.

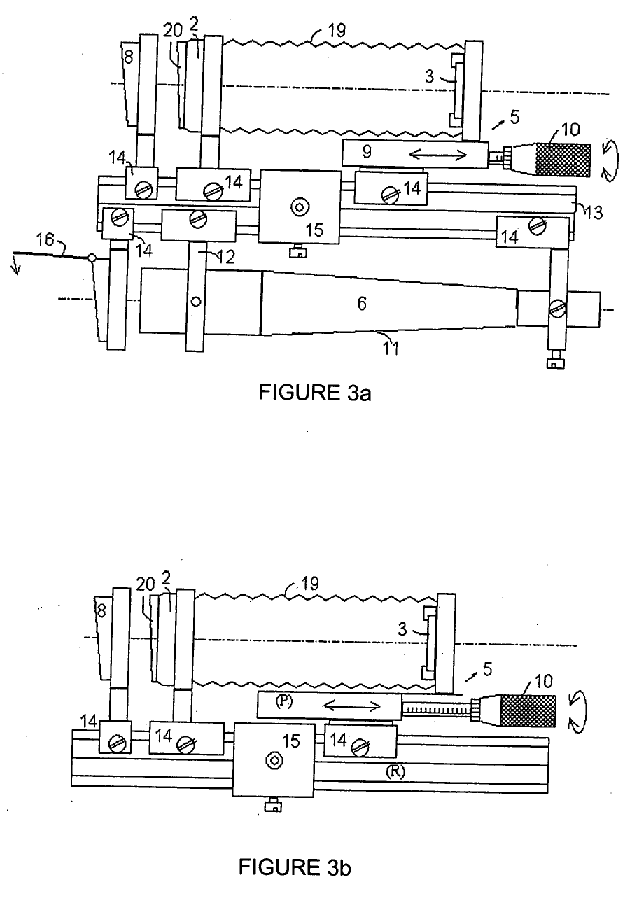

FIG. 3a shows the positions of the adjusting means that control the mirror position when the LCS is large, the mirror being near the len' focus.

FIG. 3b shows the location of the adjusting means that control the mirror position for a lesser LCS value, the mirror being far from the focus.

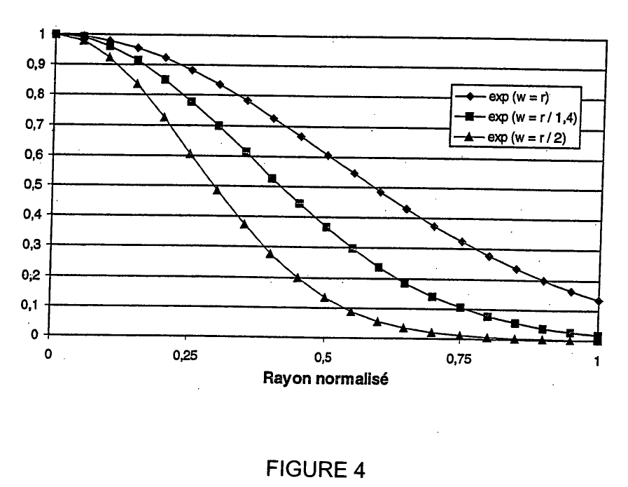

FIG. 4 shows the gaussian transmission function of a filter of a first embodiment mode of the invention.

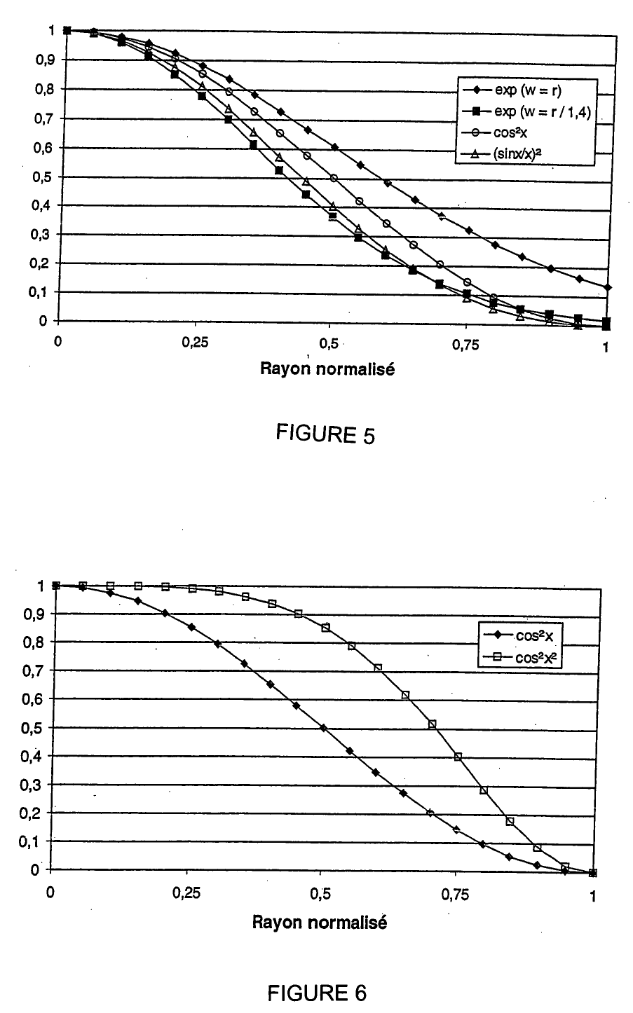

FIGS. 5 and 6 show different transmission functions of a filter of a second embodiment mode of the invention.

FIG. 1 diagrammatically shows the general means constituting a device fitted with device with a perfectly known laser cross section, said device being one embodiment variation of the invention wherein it comprises a stationary lens 2, an attenuating filter 20 with a bell-shaped optical transmission function, a mirror 3 that preferably is plane and perpendicular to the optic axis OZ, the distance x from the focus of said mirror determining, jointly with the other assembly parameters such as the mirror reflection factor R, the lens transmission factor To and said len' focal length f, the magnitude of the laser equivalent surface, said mirror's displacement in the direction of the optic axis OZ allowing continuously adjusting said magnitude.

When said distance x is sufficient that the focusing error circle be large in front of the image spot due to diffraction and aberrations corresponding to improved focusing, the value of the laser equivalent surface may be determined while neglecting said spot's size.

Under those conditions, the LCS value for this configuration is given by
LCS=_{C}RTo²f⁴/x²
where R is the mirror's reflection factor, To is the len' transmission factor and f is the len' focal length.

In the numerical illustrations below, R=T=1.

Accordingly, using a 200 mm focal length lens, an laser equivalent surface of 100 m² may be attained at an accuracy of 1% by placing the mirror at 7.09 mm±0.05 mm.

Optically this configuration is equivalent to a spherical mirror having a radius of curvature of 5.64 m. However, to attain the same accuracy, the magnitude of the 100 m² ESL when using a plain mirror having a reflection coefficient R=1 would require a radius of curvature of 5.64 m±0.03 m. That is, given an effective spherical segment diameter of 25 mm, entailing a deviation of 0.07 _{C} from the theoretical sphere, namely ¼ of a centered, circular fringe with respect to a perfect spherical size of 5.64 m in radius of curvature—which may be implemented only with difficulty. Moreover the radius of curvature would have to be matched to the reflection coefficient, entailing restriction on the scope of applicability.

The proposed design offers substantial latitude as regards manufacture and adjustment, namely:
The required adjustment is easily attained at the desired accuracy using conventional, commercially available translating devices, namely optical instruments, for instance helical mechanisms used to focus photographic equipment.
The pupil diameter need not be very large, though it must be of a size to preclude diffraction effects.

It suffices that the diffraction lobe shall be significantly narrower than the device geometrically diverging lobe.

Illustratively, if, in the first case, (100 m² ESL) a diameter of 2*rₒ=25 mm is assumed, the geometric lobe shall subtend an angle of 4.4 mrad and the diffraction lobe shall subtend an angle of 0.05 mrad at a wavelength of 1 _{C}. [The same results are attained when using the 5.64 radius of curvature mirror]. The bell curve transmission may be taken into account to refine such a result. However it may be neglected and the calculation above still leads to a satisfactory answer.

The bell-curve filter attenuating the edges of the geometric lobe reduces the device' angular tolerance. Illustratively, for a 10% tolerance in LCS, and assuming a cos²B bell-curve filter, where B=_{C}r/2r₀, said filter being crossed twice, the tolerance is reduced by the r/r₀ ratio, whence cos⁴B=0.9, hence r/r₀=0.15, therefore the tolerance is 9 mrad.

As regards the curved mirror which is subjected only once to the cos ²B factor, the tolerance is reduced by the r/r₀ ratio, whence cos²B=0.9, i.e. r/r 0a=0.21, and the tolerance is 0.45 mrad.

The device' angular tolerance is linked to the lens f/number, i.e. to its focal length f (which is reciprocal). Said angular tolerance in this instance is 62.5 mrad. It would only be 2.2 mrad using the equivalent curved mirror with the same f/number.

In this manner problems relating to the reflection coefficient and to the mechanical tolerances are precluded because the accurate LCS value is attained by optical-mechanical adjustment that can take into account the actual component performances. Therefore the system may be easily used throughout a large spectral range provided that the mirror be processed to cover said spectral range, even if such processing were imperfect and if the lens incurs chromatic aberration.

In this design, there is NO need for a plane mirror, however such a mirror may be manufactured very easily in view of the applicable tolerances. In fact the deviation relating to the mirror surface is as allowable as for the equivalent spherical mirror, however over a much smaller surface (namely that of the beam near the mirror). Accordingly the tolerance regarding the curvature is more relaxed, and quality control in one plane is simpler.

The lens must be of good quality along its optic axis, but on the other hand its focal length need not be precisely defined and manufactured. It is enough that this focal length by accurately measurable when calculating the amplitudes to be imparted to the mirror motions.

In this manner it is feasible to ascertain accurate LCS values, which are pre-set or continuously variable within a wide range of wavelengths using a single, adjusted assembly. To attain this goal, the control of the adjusted mirror may be graduated in terms of distance to the focal plane and the instrument may be fitted with nomograms showing the LCS as a function both of said distance and the wavelength. Furthermore the displacement control also may be graduated directly in terms of the LCS at the cost of the covered range of wavelengths. Also shifting may be precluded in order to derive a predetermined LCS value in order to constitute an LCS standard. Conventionally using a position pickup, a micro-monitor, control devices and optionally a display would permit automatic adjustment of mirror position relative to the focal image.

The above calculations are carried out using paraxial, geometric approximation. Such calculations allow defining instrument parameters and may be checked and if necessary be corrected when designing an instrument with real beam routings in order to take into account the bell-function filter so built and any lens aberrations. Latter may be refracting or based on mirrors.

In a second embodiment mode of the invention, shown by FIG. 2, the above described device is fitted with elements 5 to adjust the mirror position along said optic axis OZ and with elements 6 aligning said device of the invention with an external element 7. An attenuating filter 8 is configured in front of the sub-assembly consisting of the lens 2 and the attenuating filter 20 on the side of the external element 7.

Said external element 7 comprises means that may transmit laser radiation into a direction YO, further photodetectors which are able to detect any back-reflected radiation in said direction YO.

The components of this embodiment variation of the present invention, as well as their configuration, are shown in detail in FIGS. 3a and 3b, wherein the mirror is shown respectively near the focal image and far from it.

The device of the invention comprises a doublet lens 2 of 200 mm focal length, a plane mirror 3 mounted on means 5 adjusting the position of the mirror 3 along said optic axis OZ and means 6 aligning the optic axis OZ with the external element 7.

The means 5 adjusting the position of the mirror 3 along said optic axis OZ include a base plate 9 which, by rotating a knurled and graduated knob 10, allows accurately positioning the mirror 3 between the lens focus and the lens itself. Said means 5 also include a protective bellows 19 shown in axial cross-section and linking the lens 2 to the mirror 3.

The means 6 aligning the optic axis OZ to the external element 7 include a support 12 and pointing/sight means 11.

The support 12 comprises a rail 13 acting as the sub-assembly's movable part. Slides 14 allow affixing the 200 mm focal length doublet lens 2, the attenuating filter 8, means 5 adjusting the position of the mirror 3 along said optic axis OZ, and the pointing means 11 on said rail 13.

Also one slide constituting a fitting plate of the sub-assembly 15 comprises a threaded hole allowing affixing the assembly to a photographic tripod.

A shutter 16 is configured in front of the pointing means 11. The latter may assume two positions, namely one outside the pointing axis W and another wherein it masks said pointing axis, in the latter case suppressing any additional laser equivalent surface that might be generated by said pointing means 11.

Using appropriate optics, the pointing means 11 might be made co-linear with the instrument axis. In the shown embodiment variation, however, said pointing means 11 is configured laterally to it. Parallax is entailed, which might be compensated in known manner or be neglected because remaining slight on account of the large distances that are involved, alignment tolerances not being critical as shown in the above numerical illustration.

Any pointing/sight means may be used. When a telescope is involved, considering its own poorly controlled LCS, it must be fitted with masking elements applied during instrument use in order to prevent its own LCS to that of the instrument When a foresight and a peep-hole are involved, such as in a rifle, only a negligible LCS shall be involved.

The pointing system is adjusted, i.e. its axis is made parallel to that of the instrument, at the factory using conventional optic procedures.

The attenuating filter 8 allows varying or adjusting the LCS of the device of the invention.

Preferably said filter shall be absorbing rather than reflecting in order to reduce the danger of uncontrolled interferences in the operating instrument being used. Even when treated to be non-reflecting, this filter exhibits residual reflection and must be inclined to prevent, on one hand, that it might contribute to the back-reflection toward the monostatic transmitting/receiving apparatus, and on the other hand to preclude deflecting toward said apparatus the reflection from an external source, for instance from the sun, or the back reflection from another instrument. Frequently a slight inclination toward the ground is sufficient, though said filter also may be oriented in a manner that the laser's reflection shall be incident on a light trap which then acts as a screen suppressing any reflection of parasitic sources.

Under such conditions, assuming the filter's transmission factor is T_{f} at the laser's wavelength, then the instrument's laser equivalent surface shall be multiplied by the square of said factor, namely T_{f}².

This filter's transmission may be fixed or continuously variable to make an instrument which is continuously adjustable in its ESL and discretely variable to attain discrete adjustment of LCS or to widen the scope of application of an apparatus having a variable laser equivalent surface.

Using such a filter of which the attenuation varies as a function of wavelength independently of the variation of the LCS of the instrument on which it is mounted will render system operation if a wide band of wavelengths must be covered.

Operation of an apparatus of the invention is especially user-friendly. The manufacturer adjusts the relative axes orientation (harmonization), locks in place the adjustments and provides the nomograms of the instrument's LCS value as a function of wavelength and base plate position.

The user only need affixing the assembly onto a photographic tripod near the matching base plate 15, adjust the orientation by means of said tripod by using the sighting telescope 11, the shutter being open—and then close the masking flap 16 and adjust the position of the base plate 9 by merely rotating the knurled control knob 10 to the value read off the nomograms.

The broadening of the scope of application and of reliability of the reflecting spherical segment apparatus, those fitted with reflecting trirectangular dihedra or according to the patent application WO02/33438, even the feasibility of passing continuously from a system based on geometric properties to a diffraction-limited one, is carried out configuring an attenuator 20 near the instrument's pupil plane, namely the plane containing the diaphragm and ideally in the very plane itself, said attenuator exhibiting a radial transmission curve (distributed in revolution about the system's optic axis) in the shape of a bell curve. This attenuator alters the luminous power distribution in the pupil plane which thereupon is constrained by the attenuator's transmission function and thereby the propagation of the transmitted beam also is altered.

Accordingly a first solution consists in fitting the apparatus system with a filter 20 of which the radial transmission follows a gaussian distribution having a small radius compared to that of the diaphragm in a manner that the truncation exerted by said diaphragm eliminates only a very low proportion of the theoretically available power under the gaussian curve and shall only negligibly interfere with the gaussian's “ideal” propagation. The propagation functions of the gaussian-distribution beams then allow easily calculating the instruments LCS.

FIG. 4 shows three gaussian distribution radii w=r, w=r/1.4 and w=r/2, where w is the gaussian radius when the gaussian curve is 1/e² of its maximum and r is the truncating radius due to the Figure's normalized diaphragm (r=1). The r=w truncation eliminates 13.8% of the total gaussian power; this lacking power disturbs propagation and may cause undesirable modulations. Truncation at r=1.4 w eliminates another 2% of the total power while the truncation at r=2 w only eliminates a negligible 0.034% of the total power. Accordingly, the smaller the gaussian radius, the closer the ideal propagation so attained, but simultaneously the power received by the instrument is reduced as well as the acceptable system orientation error which would not disturb its LCS value.

Distributions other than the gaussian one may offer satisfactory solutions provided some rules be observed that are based on pragmatically evaluating computations of different distributions in the particular instrument pupil.

A priori radial and revolutionary distributions are selected of which the function decreases monotonely from the pupil center to its rim. The transmission is set at unity at the pupil center, though this is not mandatory; a different value T, may be shown by adding an attenuator to the uniform distribution that would alter the power transmitted in the system and then reflected back, thereby multiplying the LCS of the system by Tc², but this feature would not at all affect the modulation problem addressed herein.

Preferably this distribution shall entail the following properties:
It is defined inside the material diaphragm defining the system pupil, preferably decreasing monotonely from the pupil center to the pupil rim.
It preferably comprises a horizontal tangent to the center.
Its value is very low, preferably zero, at the pupil rim.
Preferably it is free of discontinuities and sharp angles in the range of its definition, or, in other words, the slope of the surface representing the transmission function is free of discontinuities.
Preferably it approaches zero value at the pupil rim while joining the horizontal tangent.

Such distributions may be attained, exhibiting the following, illustrative transmission functions: T=sin²A/A², where A=_{C}r/r₀ and T=cos²B, where B=_{C}r/2r₀.

FIG. 5 shows such curves in comparison with two gaussian curves of larger radius. Be it borne in mind that said curves are very close to said gaussian ones but are lacking truncation generating interfering high frequencies.

A transmission function T=cos²B² compared with the function T=cos²B, where (B=_{C}r/2r₀) as shown in FIG. 6, exhibits a substantial transmission gain and a very flat curve at the pupil center as regards the former of these two functions. On the other hand this distribution departs significantly from the gaussian one.

Because the filters are being crossed twice, one might assume that their squared transmission function need not be high because being due to double crossing. This assumption however is not always the case where the beams will not necessarily cross the pupil at the same place.

Similarly to the case of the filter 8, however with the additional constraint that the bell shaped filter functions in general entail reflecting layers, the filter 20 having a bell-shaped function slightly inclines relative to the optic axis OZ, preferably in a way not to be parallel to the filter 8 in order to preclude interference between the two filters.

As regards systems consisting of a simple spherical segment, it may be processed directly with a reflecting property generating a reflected beam having such a power distribution. In that event the previously discussed functions no longer would be filter transmission functions but direct mirror reflection functions. A uniformly processed spherical segment also may be fitted with an attenuating filter. In this case, if the filter is fairly close to the spherical segment, its transmission function might be of the first degree (sinA/A or cosB), the double crossing at two practically coinciding points entailing squaring.

LCS calculations regarding non-gaussian distributions in principle entail theoretical computations that may be carried out using commercially available optic computation software.

As regards a highly defocused instrument such as described in the patent application WO02/33438, or as regards a spherical segment, the geometric calculation disclosed in this application will be applicable regardless of distribution.

It is understood that many alterations may be applied to the above illustrative embodiment without thereby transcending the scope of the present invention.

1. Device with a perfectly known laser cross section and able to measure the performance of an active sight laser detection system comprising a pupil, wherein
said apparatus comprises a radial attenuator (20) able to modify said apparatu' aperture and having a radial, bell-shaped transmission function.

2. Device as claimed in claim 1, wherein the radial attenuator (20) is placed in the pupil plane.

3. Device as claimed in either of claims 1 and 2, wherein the transmission function includes symmetry of revolution.

4. Device as claimed in any of claims 1 through 3, wherein the transmission function monotonely decreases from the pupil's center to its rim.

5. Device as claimed in any of claims 1 through 4, wherein the transmission function is substantially sinusoidal.

6. Device as claimed in any of claims 1 through 5, wherein the slope of the surface representing the transmission is free of any discontinuity across all of the pupil.

7. Device as claimed in any of claims I through 5, wherein it includes a lens (2) and a mirror (3) configured in a way to subtend at least one optic axis OZ and being situated at a distance x from the image focus F′, x being different from 0.

8. Device as claimed in any of claims 1 through 5, wherein it comprises a lens (2) a mirror (3) configured in a way to subtend at least one apparatus optic axis (OZ) and means (5) adjusting the distance between the lens (2) and the mirror (3).

9. Device as claimed in claim 8, wherein it comprises a stationary lens (2), a mirror (3) and means (5) adjusting the position of the mirror (3) to adjust the distance between the lens and the mirror.

10. Device as claimed in claim 8, wherein it comprises a stationary mirror (3) and means adjusting the position of the lens (2) to adjust the distance between the lens and the mirror.

11. Device as claimed in either of claims 8 and 9, wherein said adjusting means (5) include a stepping motor.

12. Device as claimed in any of claims 9 through 11, wherein the means (5) adjusting the mirror position along the said optic axis include a helical mechanism.

13. Device as claimed in any of claims 9 through 12, wherein it includes means (10) controlling said means (5) and able to adjust the mirror position along said optic axis.

14. Device as claimed in claim 13, wherein the control means (10) comprise a setpoint expressed in terms of laser equivalent surface.

15. Device as claimed in any of claims 7 though 14, wherein said mirror is plane.

16. Device as claimed in any of claims 7 through 15, wherein said mirror is perpendicular to said len' optic axis.

17. Device as claimed in claim 1, wherein it consists of a reflecting spherical segment.

18. Device as claimed in claim 17, wherein the spherical segment has been processed to reflect radially, the reflection coefficient being a bell-shaped curve.

19. Device as claimed in claim 1, wherein it consists of a reflecting trirectangular trihedral.

20. Device as claimed in claim 1, wherein it comprises a lens and diffusing surface situated at its focus or near it.

21. Device as claimed in claim 1, wherein it comprises a lens and a reflecting surface situated at its focus or near it.
